(19) United States
(12) Patent Application Publication
(10) Pub. No.: US 2016/0301190 A1
(43) Pub. Date: Oct. 13, 2016

(54) LASER DEVICE

(71) Applicant: CLEVERWAVE TECHNOLOGY INC., Taoyuan County (TW)

(72) Inventors: Ching-Chuan LEE, Taoyuan County (TW); Chi-Luen WANG, Taoyuan County (TW)

(73) Assignee: CLEVERWAVE TECHNOLOGY INC., Taoyuan County (TW)

(21) Appl. No.: 13/956,806

(22) Filed: Aug. 1, 2013

(30) Foreign Application Priority Data
Jul. 1, 2013 (TW) 102212321

(51) Int. Cl. H01S 5/0683; H01S 5/022

(52) U.S. Cl. CPC H01S 5/0683; H01S 5/02252

(57) ABSTRACT

A laser device includes a laser diode bracket, a photodiode bracket, a laser diode, a photodiode, and an auto power control PCB (automatic power control printed circuit board). The photodiode bracket is configured on the laser diode bracket. The laser diode is configured on the laser diode bracket. The photodiode is configured on the photodiode bracket and on a lateral surface in which the laser diode emits laser a laser beam. In other words, out of a path of an optical axis of the laser beam. The auto power control PCB delivers a driving current such that the laser diode sends one laser beam. The photodiode detects the optical power of the laser beam and generates a feedback signal transmitted to the auto power control PCB for comparison in order to control the stability and reliability of optical output power by the laser diode.

### BACKGROUND OF THE INVENTION

1. Field of the Invention

The instant disclosure relates to a laser power control device; in particular, to a laser device which controls the stability of the laser power through the addition of a photodiode outside a laser diode.

2. Description of Related Art

Laser devices may include a laser diode and a photodiode package within the laser diode. The laser diode is the source of laser beams. The photodiode in the laser diode can detect portions of the laser beams, and the laser device can control the output power of the laser diode via the automatic power control (APC) circuit. For example, the laser device can maintain stable output power by detecting the optical power of the laser beam source and controlling the electrical current value of the laser diode via feedback signals.

In a typical laser device, laser emitting chip and photodiode are designed to be packaged in the same laser diode for automated power control. However, since the size of the photodiode is limited when packaged in a laser diode, detection tends to be saturated for the relatively high optical power lasers. Thus, the relatively high powered laser devices are not preferred for such application. As a result, much high powered laser diodes omit the design of photodiodes.

However, with the omission in photodiode design, laser devices can only use automatic current control (ACC) circuit, which uses constant electric current to control the power of the laser diode. The laser diode with constant electric current cannot ensure the stability of the laser output power, and the output power of the laser diode may also be affected by temperature. Whenever temperature changes or after a prolong period of usage which leads to an increase in temperature of the laser device, the laser diode output efficiency changes. In turn, the power of the laser becomes unstable and unreliable.

### SUMMARY OF THE INVENTION

The object of the instant disclosure is to provide a laser device, which includes laser diode and photodiode, capable of controlling the stability of the laser output power emitted by the laser device.

The instant disclosure provides a laser device including a laser diode bracket, a photodiode bracket, a laser diode, a photodiode, and an auto power control PCB (automatic power control printed circuit board). The laser diode is configured on the laser diode bracket and emits a laser beam. The photodiode is configured on the photodiode bracket and to not be in direct alignment with an optical axis of the laser beam. An auto power control PCB is electrically connected to the laser diode and photodiode. The auto power control PCB delivers a driving current such that the laser diode sends one laser beam. The photodiode detects the optical power of the laser beam and generates a feedback signal. The auto power control PCB compares the strength of the predeterminate value with the feedback signal and adjusts a driving current of the laser diode to maintain stability of the laser output power by the laser diode.

In summary, the instant disclosure provides a laser device which includes a laser diode, and a photodiode. The laser diode emits a laser beam whose output power is detected by the photodiode such that feedback signals are provided to the auto power control PCB for comparison. The driving current of the laser diode can be adjusted, and in turn the output power of the laser diode is adjusted to provide stable power output for the laser beam.

In order to further understand the instant disclosure, the following embodiments and illustrations are provided. However, the detailed description and drawings are merely illustrative of the disclosure, rather than limiting the scope being defined by the appended claims and equivalents thereof.

### BRIEF DESCRIPTION OF THE DRAWINGS

FIG. 1 is a schematic diagram of a laser device in accordance with a first embodiment of the instant disclosure;

FIG. 2 is a schematic diagram illustrating output optical power and driving current with respect to temperature change of the laser device in accordance with the first embodiment of the instant disclosure;

FIG. 3 is a schematic diagram illustrating output optical power with respect to temperature and time change of the laser device in accordance with the first embodiment of the instant disclosure;

FIG. 4 is a schematic diagram illustrating the power at a constant driving current with respect to temperature and time change of a typical laser device without photodiode; and

FIG. 5 is a schematic diagram illustrating the output power at a constant driving current with respect to temperature and time change of a typical laser device without photodiode.

### DETAILED DESCRIPTION OF THE PREFERRED EMBODIMENTS

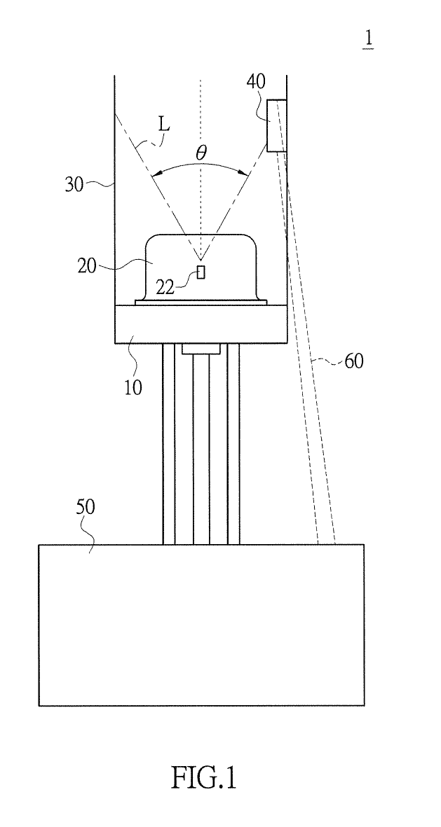

FIG. 1 is a schematic diagram illustrating the structure of a laser device in accordance with a first embodiment of the instant disclosure. Please refer to FIG. 1. The laser device 1 includes a laser diode bracket 10, a laser diode 20, a photodiode bracket 30, a photodiode 40, and an auto power control PCB (automatic power control printed circuit board) 50.

The laser diode 20 includes a laser chip 22 as shown in FIG. 1. The laser diode 20 is connected to the auto power control PCB 50. The laser chip 22 can emit a laser beam L. When the laser chip 22 emits the laser beam L, heat is generated, and thus temperature of the laser device 1 is changed which affects the effectiveness of the laser chip 22.

The photodiode bracket 30 is configured on the laser diode bracket 10, and the photodiode 40 is configured on the photodiode bracket 30. In other words, the photodiode 40 is configured above the laser diode 20, and the photodiode 40 is configured in an optical path of the laser beam L yet not directly aligned with the optical axis of the laser beam L. That is to say, the photodiode 40 is fixed laterally with respect to the laser diode 20.

Notably, an optical axis is an axis of the laser beam L. In other words, when the laser diode 20 emits the laser beam L, the photodiode 40 will not interfere with the travel path of laser beam L. Instead, the photodiode 40 receives portions of the laser beam L emitted by the laser diode 20.

For example, the laser device 1 in the instant embodiment can be purple, red, blue, or green laser. The divergence angle 6 of the laser beam L is about 4 to 40°. As a result, the photodiode 40 is configured to not directly align with the optical axis, or out of travel path of the optical axis, where the optical axis of the laser beam L is in the center of the laser beam L. However, the laser device 1 in another embodiment can be other types of light sources, and is not limited to the example provided herein. In addition, the angle and the position of the photodiode 40 can be adjusted according to the type of light source being applied.

Furthermore, the laser device 1 includes the auto power control PCB 50. The automatic power control PCB electrically connected to the laser diode 20 and photodiode 40. In practice, the auto power control PCB 50 outputs a current signal to the laser diode 20 such that the laser diode 20 emits a laser beam L. The photodiode 40 detects the actual output optical power of the laser beam L from the laser diode 20. Once detected, the photodiode 40 generates feedback signals which are transmitted to the auto power control PCB 50 via the photodiode feedback signal wire 60.

Then, the auto power control PCB 50 compares the preset current signal with the feedback signal. If the feedback signal detected by the photodiode 40 is relatively weak, an increase in current will be accordingly provided to the laser diode 20 to increase the strength of the laser beam L until whose predetermined value is reached. Conversely, if the feedback signal is relatively strong, the driving current of the laser diode 20 will be reduced, thus reducing the intensity of the laser power until whose predetermined value is reached. As a result, signal comparison and current adjustments by the auto power control PCB 50 facilitate the laser device 1 to output laser beams L with stable power at various temperatures and for prolong periods of use. The magnitude of the optical power is adjusted according to the laser devices preferred by the user, and therefore is not limited by the examples provided herein.

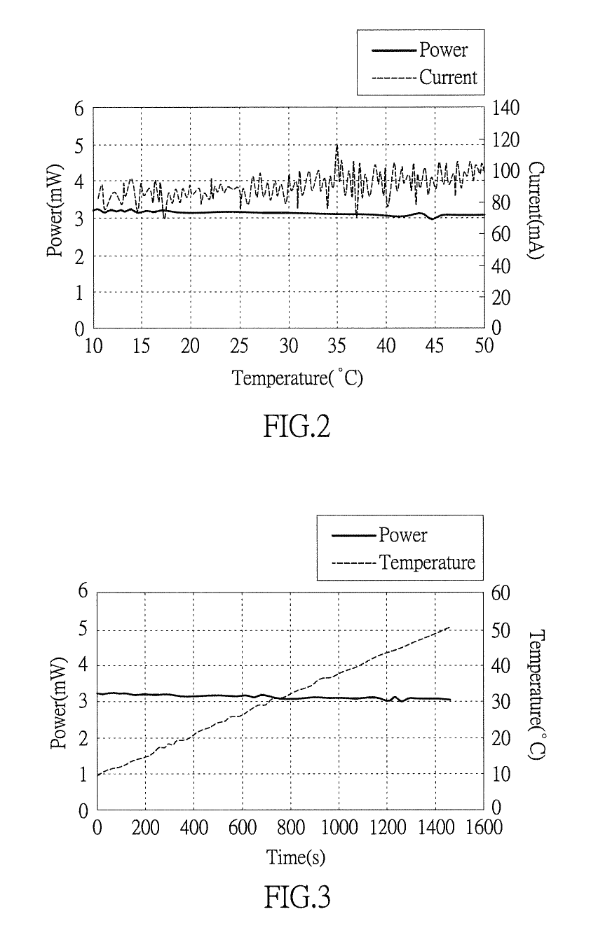

Notably, the photodiode 40 receives feedback signals, and along with the auto power control PCB 50, stable output power of the laser diode 20 is maintained. Please refer to FIGS. 2 and 3. FIG. 2 is a schematic diagram illustrating output optical power and driving current with respect to temperature change of the laser device 1 in accordance with the first embodiment of the instant disclosure, and FIG. 3 is a schematic diagram illustrating output optical power with respect to temperature and time change of the laser device 1 in accordance with the first embodiment of the instant disclosure. As shown in FIG. 2, the output power of the laser diode 20 shows insignificant change as temperature changes, whereas the driving current slightly fluctuates in order to maintain stable output power of the laser beam. Moreover, as shown in FIG. 3, the output power of the laser diode 20 is still stable after a prolong period of use. In other words, the instant disclosure can maintain stable output power via the cooperation between the feedback signals received by the photodiode 20 and the control over the light intensity emitted from the laser diode 20 by the auto power control PCB 50.

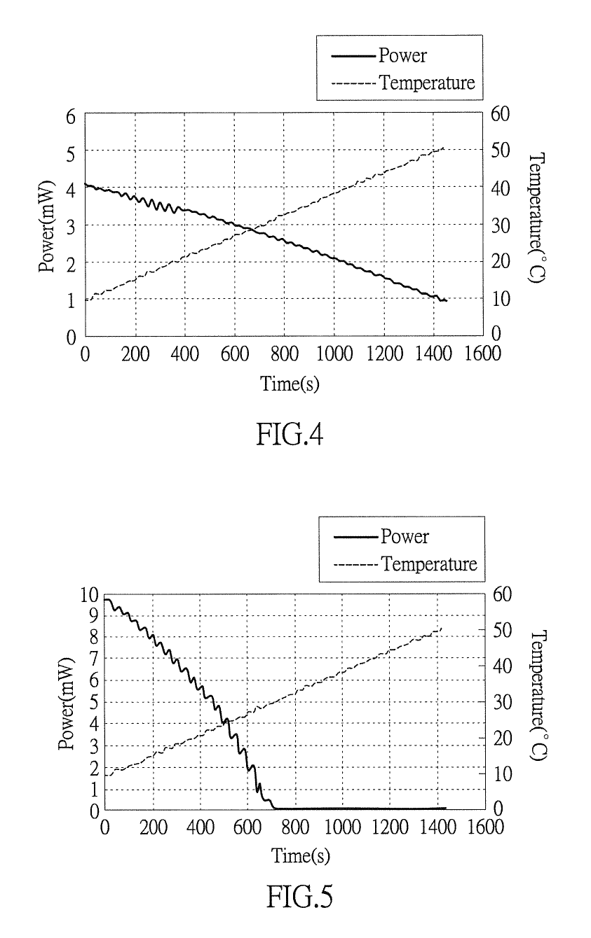

Furthermore, please refer to FIG. 4 as a schematic diagram illustrating the power at a constant driving current with respect to temperature and time change of a typical laser device without photodiode and FIG. 5 as a schematic diagram illustrating the output power at a constant driving current with respect to temperature and time change of a typical laser device without photodiode. Prior technology uses control loop with constant current to control the output power of the laser diode.

As shown in FIGS. 4 and 5, with typical laser devices which use constant current, the power of the laser reduces as the temperature increases. When the temperature of the laser diode reaches a certain temperature and if the constant current continues to drive the laser diode, the output power of the laser beam might eventually be reduced to about 0 mW.

As shown in FIGS. 2 to 5, the instant disclosure can maintain a stable output power for the laser beam L emitted at various temperature via the cooperation between the feedback signals received by the photodiode 20 and the control over the current of the laser diode 20 by the auto power control PCB 50.

Moreover, apart from prior technology where photodiode is packaged in the internal structure of the laser diode, the instant disclosure provides photodiode 40 which is configured outside of the laser diode 20. As a result the type and size of the photodiode 40 is not limited herein. When a high power laser diode 20 is preferred, the appropriate photodiode 40 can be selected to suit the high power requirement of the laser diode 20.

Please refer again to FIG. 1, the laser device 1 can also include a focusing lens (not shown in figures). The focusing lens is configured on the laser diode 20 and covers the laser diode 20 and the photodiode 40 and the optical axis of the laser beam L can pass through the focusing lens. The focusing lens can modify the beam pattern of the laser beam L in order to focus and provide preferred light properties.

In summary, the instant disclosure provides a laser device which includes a laser diode, and a photodiode. The laser diode emits a laser beam whose output power is detected by the photodiode, such that the driving current of the laser diode can be adjusted accordingly to provide stable intensity for the laser power.

The figures and descriptions supra set forth illustrated the preferred embodiments of the instant disclosure; however, the characteristics of the instant disclosure are by no means restricted thereto. All changes, alternations, combinations or modifications conveniently considered by those skilled in the art are deemed to be encompassed within the scope of the instant disclosure delineated by the following claims.

What is claimed is:

1. A laser device, comprising:
a laser diode bracket;
a photodiode bracket configured on the laser diode bracket;
a laser diode configured on the laser diode bracket and emitting a laser beam;
a photodiode configured on the photodiode bracket and out of a travel path of an optical axis of the laser beam; and
an automatic power control PCB electrically connected to the laser diode and photodiode;
wherein the automatic power control PCB delivers a driving current such that the laser diode sends one laser beam, the photodiode detects the optical power of the laser beam and generates a feedback signal, and the automatic power control PCB compares the strength of the predeterminate value with the feedback signal and adjusts an driving current of the laser diode to maintain stability of the laser output power by the laser diode.

2. The laser device as recited in claim 1, wherein the laser device further includes a focusing lens configured above the laser diode covering the photodiode and the laser diode, and the optical axis of the laser beam passes through the focusing lens.
